(19) United States
(12) Patent Application Publication
(10) Pub. No.: US 2005/0272179 A1
(43) Pub. Date: Dec. 8, 2005

(54) Three-dimensional lithographic fabrication technique

(76) Inventor: Andrew Frauenglass, Albuquerque, NM (US)

Correspondence Address: SCHWEGMAN, LUNDBERG, WOESSNER & KLUTH, 1600 TCF TOWER, 121 SOUTH EIGHT STREET, MINNEAPOLIS, MN, 55402, US

(21) Appl. No.: 11/136,306

(22) Filed: May 24, 2005

Related U.S. Application Data
(60) Provisional application No. 60/573,958, filed on May 24, 2004.

(51) Int. Cl. H01L 21/42

(52) U.S. Cl. 438/31; 438/795; 430/269; 257/618; 257/432

(57) ABSTRACT

Embodiments of a structure and embodiments of methods for fabricating structures provide three dimensional features defined by exposure to multiple wavelengths of light. In an embodiment, material is exposed to two different wavelengths of light. Embodiments of three dimensional structures may provide a variety of three-dimensional structural features and characteristics.

### RELATED APPLICATION

This application claims priority under 35 U.S.C. 119(e) from U.S. Provisional Application Ser. No. 60/573,958 filed on 24 May 2004, which application is incorporated herein by reference.

### GOVERNMENT FUNDING

The invention described herein was made with government support under the following grant numbers, DAAD19-99-1-0196 (ARO-MURI). The United States Government may have certain rights in the invention.

### FIELD OF THE INVENTION

This invention relates generally to techniques for lithographic fabricating of structures.

### BRIEF DESCRIPTION OF THE DRAWINGS

Embodiments, aspects, advantages, and features of the present invention will be set forth in part in the description which follows, and in part will become apparent to those skilled in the art by reference to the following description of the invention and referenced drawings. The aspects, advantages, and features of the invention are realized and attained by means of the instrumentalities, procedures, and combinations particularly pointed out in these embodiments and their equivalents.

FIG. 1 depicts an embodiment of elements of a method to form multiple layers in which multiple wavelengths are applied, in accordance with the teachings of the present invention.

FIGS. 2A-2G depicts an embodiment in which material is exposed to light at an absorbed wavelength and light at a transmitting wavelength to form a three-dimensional structure, in accordance with the teachings of the present invention.

FIGS. 3A-3G depicts features an embodiment in which a ring structure may be formed using multiple wavelengths, in accordance with the teachings of the present invention.

FIG. 4 depicts an embodiment of a gear on a substrate formed using multiple wavelengths, in accordance with the teachings of the present invention.

FIG. 5 depicts an embodiment of a stack structure formed using multiple wavelengths, in accordance with the teachings of the present invention.

FIG. 6 depicts an embodiment of suspended structures formed using multiple wavelengths, in accordance with the teachings of the present invention.

FIG. 7 depicts an embodiment of a tunnel having a T shape formed using multiple wavelengths, in accordance with the teachings of the present invention.

FIGS. 8A-8B depict an embodiment of a single stage filter using multiple wavelengths, in accordance with the teachings of the present invention.

FIGS. 9A-9G depict an embodiment in which a two-stage filter may be formed using multiple wavelengths, in accordance with the teachings of the present invention.

FIG. 10 depicts an embodiment of a filter stack formed using multiple wavelengths, in accordance with the teachings of the present invention.

FIGS. 11A-11B depicts an embodiment of disc stacks formed using multiple wavelengths, in accordance with the teachings of the present invention.

FIG. 12 depicts an embodiment of a molecular sieve formed using multiple wavelengths, in accordance with the teachings of the present invention.

FIG. 13 depicts an embodiment of a superstructure for metal evaporation using various trajectories, in accordance with the teachings of the present invention.

FIG. 14 depicts an embodiment of an air-bridge optical waveguide fabricated using multiple wavelengths, in accordance with the teachings of the present invention.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the present invention. Other embodiments may be utilized and structural, logical, and electrical changes may be made without departing from the scope of the invention. The various embodiments disclosed herein are not necessarily mutually exclusive, as some disclosed embodiments can be combined with one or more other disclosed embodiments to form new embodiments. The following detailed description is, therefore, not to be taken in a limiting sense, and the scope of the embodiments of the present invention is defined only by the appended claims, along with the full scope of equivalents to which such claims are entitled.

In an embodiment, light at multiple wavelengths is applied to a material to provide a three-dimensional image in the material that can be processed to generate a three-dimensional structure. In an embodiment, light at two different wavelengths is applied to a material to provide a three-dimensional image in the material that can be processed to generate a three-dimensional structure. In an embodiment, a new fabrication technique can rapidly build complex 3D micro-structures and nano-structures in a single efficient low-cost process. With this new technique, three-dimensional structures are fabricated within a single layer of material and processed in one development. Embodiments provide the ability to build microfluidic devices directly on semiconductor devices. Microfluidic devices include microfluidic mixers, biofluidic filters and separators, integrated fluidic vents, fluidic micromotors, biosensor size filters, electroosmotic flow devices, controlled drug delivery systems, and other devices and systems.

In general, most photo-resist and photo-epoxy materials in micro-lithography employ a strategy that results in a two-dimensional pattern printed in a material with the same pattern (or exact reverse) as the light image used to expose that material. The material transparency to the exposure wavelength allows the projected image to expose the material completely from top to bottom. This results in an accurate and functional two-dimensional reproduction of the two-dimensional image or pattern projected in the exposure. In this way, current state of the art, photolithography can accurately transfer two-dimensional images onto materials for micro-technology and nano-technology processing. For three-dimensional structures in photo-polymers the same strategy is used. Exposures are projected in a wavelength that penetrates totally through a thick layer or layers of photo-polymerized material. As the image or pattern passes through the material, it exposes all the material along the optical path. Other images are projected through at different angles building up a composite 3D structure. The structure is composed of the sum of all the images and their optical paths and intersections through the material. Even though this process is fast and requires only one development sequence, it is limiting. It is limiting because all the structure designs must incorporate all the optical paths and intersections in the final structure. This means that all the features of the structure are linear in nature and connected at optical path intersections. This makes complex individual 3D features impossible in a single develop process.

Various embodiments of the present invention create a design strategy for fabricating three-dimensional micro-structures in photo-initiated polymer materials. However, embodiments are not limited to micro-structures in photo-initiated polymer materials. In an embodiment, a technique uses different wavelength exposures to fabricate the different types of features comprising 3D structures. An exposure wavelength absorbed near the surface of a photo-polymer material may be used for one set of features. An exposure at a wavelength that penetrates completely through the material may be used for a different set of features.

In an embodiment, two different wavelength exposures are designed to project different 3D feature characteristics. One exposure wavelength may create the above plane elevated features. These features are designed to be elevated away from the plane of the substrate. These features include roofs, shapes atop posts, bridges, tops of arches, elevated pathways, and many other new elevated feature design possibilities. These features may be processed with a wavelength that is totally absorbed in the upper region of the material. This exposes the upper portion of the material only but leaves the underlying material unexposed and able to be developed away.

To prevent these features from floating away due to the unexposed material underneath being developed away, an exposure in a traditional wavelength that fully penetrates the material may be used. The features designed for this penetrating exposure result in the support structures that connect the top surface features to the substrate. These types of features include walls, pillars, support scaffolding, , and because this is a new design strategy, many other new types of 3D functional vertical elements.

Once the exposures are completed, the material may be developed and all the unexposed material may be removed from around and under the exposed material. The remaining material is the designed three-dimensional structure. Multiple process sequencing can produce complex features required for many research and production applications. Relevant fields include, but are not limited to, photonic crystal applications, microfluidic applications, nano-fluidic applications, biological applications, new photonics materials, new micro and nano-technology physics applications, artificial composites, particle separators, metamaterial structures, and volumetric information recording. The technique can build structural frameworks useful for new bio-computer designs, microelectronic devices, and combined electromagnetic and microfluidic systems.

In an embodiment, photosensitive material used can be processed in both single and multiple process sequence scenarios.

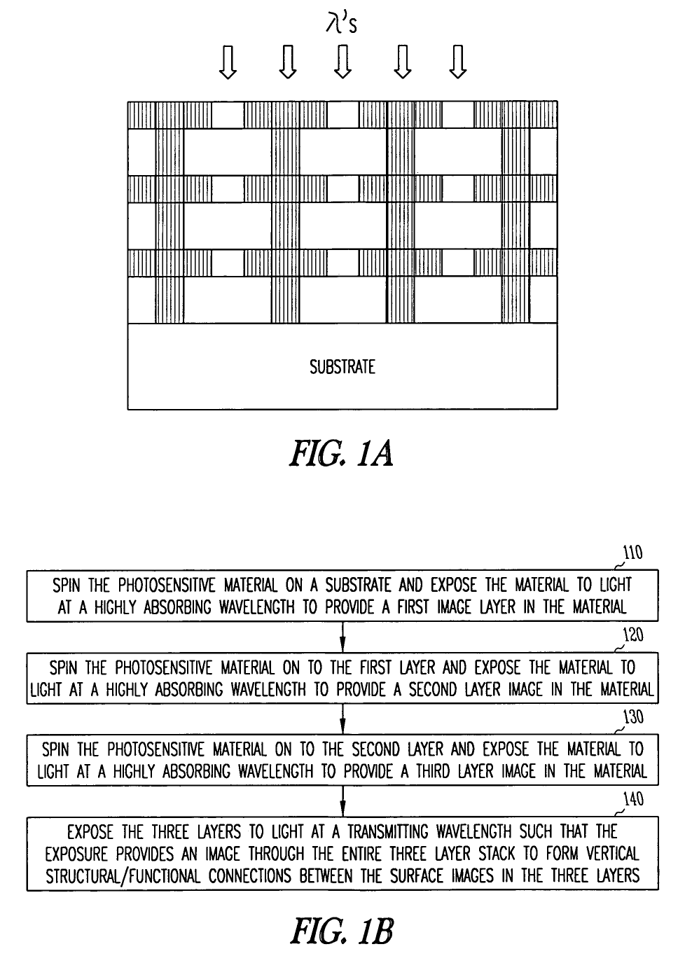

FIG. 1 depicts an embodiment of elements of a method to form multiple layers in which multiple wavelengths are applied. At 110, photosensitive material may be spun on a substrate and exposed to light at a highly absorbing wavelength to provide a first image layer in the material. The image in the first layer of photosensitive material has a depth less than the thickness of the first layer material dependent upon the absorption properties of the material at the absorbing wavelength. At 120, photosensitive material may be spun on to the first layer and exposed to light at a highly absorbing wavelength to provide a second layer image in the material. The image in the second layer of photosensitive material has a depth less than the thickness of the second layer material dependent upon the absorption properties of the material at the absorbing wavelength. At 130, photosensitive material may be spun on to the second layer and exposed to light at a highly absorbing wavelength to provide a third layer image in the material. The image in the third layer of photosensitive material has a depth less than the thickness of the third layer material dependent upon the absorption properties of the material at the absorbing wavelength. At 140, the three layers are exposed to light at a transmitting wavelength such that the exposure provides an image through the entire three layer stack to form vertical structural/functional connections between the surface images in the three layers. A mask may be used with the light at the transmitting wavelength. Embodiments of a process sequence is not limited to two or three layers but may be used with any number of layers. The three layers exposed to light at the absorbing and transmitting wavelengths may be developed to form the three-dimensional features.

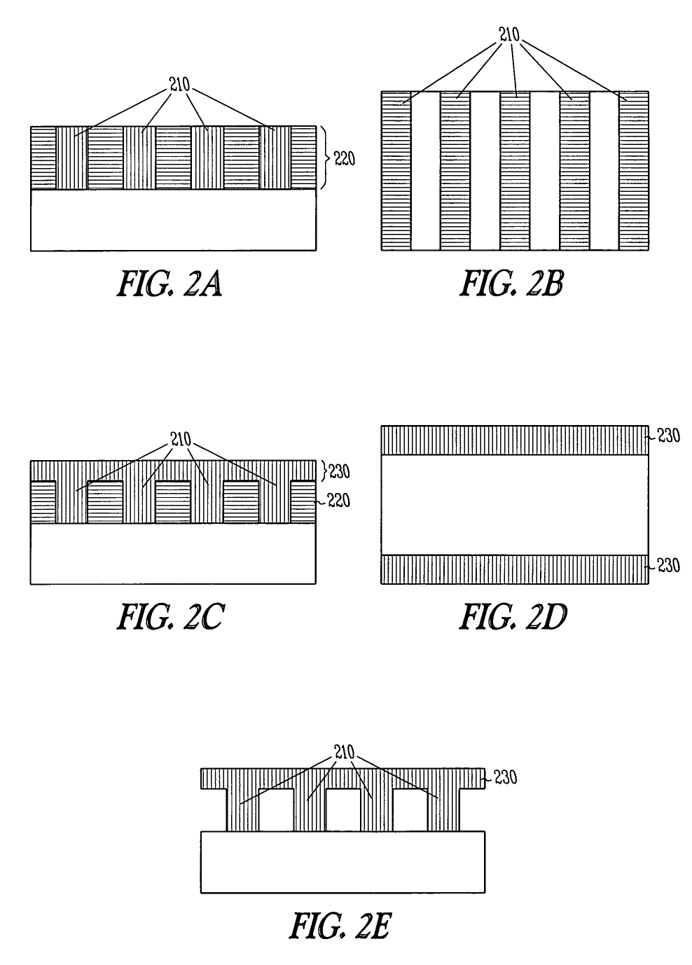

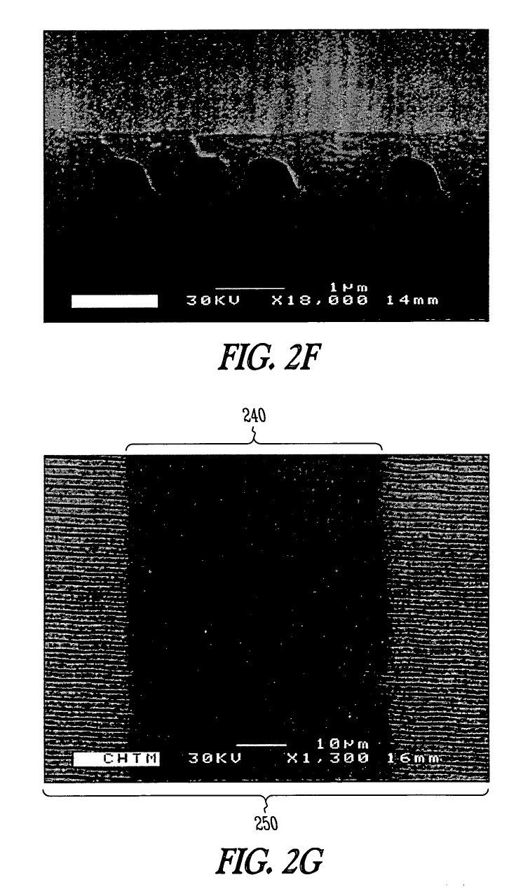

FIG. 2A-2H depicts an embodiment in which material is exposed to light at an absorbed wavelength and light at a transmitting wavelength to form a 3-D structure. FIG. 2A shows an embodiment in which area 210 in negative resist material 220 exposed to light at 355 nm. The resist may be SU-8 material. The light at 355 nm provides an image mask that penetrates through entire resist material 220. FIG. 2B shows a top view of FIG. 2A. FIG. 2C shows an area 230 at the top of resist material 220 exposed to light at 244 nm that is absorbed by resist material 220. FIG. 2D shows a top view of FIG. 2C. FIG. 2E shows resist material 220 of FIG. 2C after developing resist material 220 exposed to the two wavelengths of light. FIG. 2F shows a scanning electron microscope (SEM) image of a structure formed as in FIGS. 2A-2E. FIG. 2G shows a SEM image of a structure formed in FIG. 2F, having a roof 240 provided by exposure at 244 nm and walls 250 separating tunnels provided by exposure at 355 nm over the entire area.

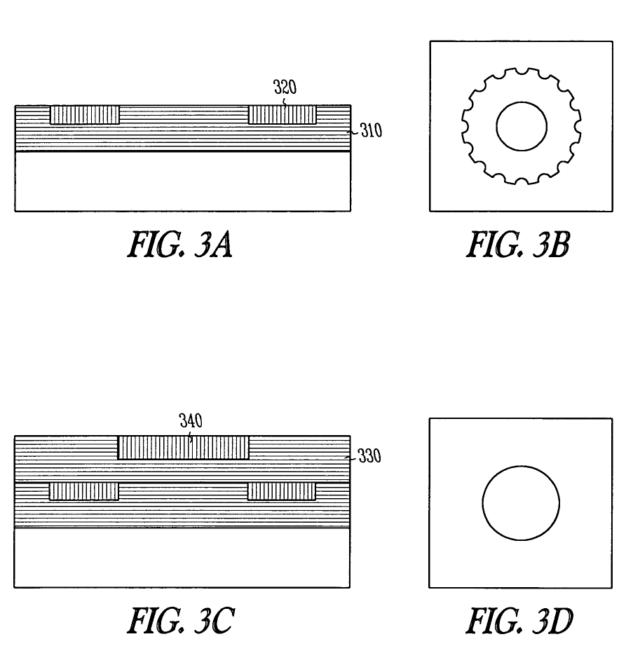

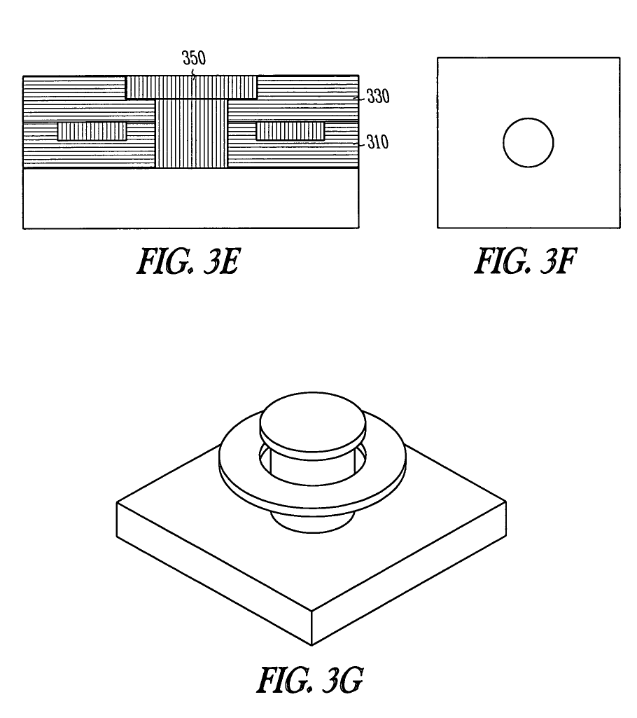

FIGS. 3A-3G depicts an embodiment in which a ring structure may be formed using multiple wavelengths. FIG. 3A shows a negative resist material 310 on a substrate to form a first layer. The resist may be SU-8 material. Resist material 310 may be exposed to light at a wavelength that is absorbed within region 320. FIG. 3B shows a top view of FIG. 3A of a first layer mask at absorbing light exposures. FIG. 3C shows a second layer of negative resist material 330. The resist may be SU-8 material. Second resist material 330 may be exposed to light at a wavelength that is absorbed within region 340. FIG. 3D shows a top view of FIG. 3C of a second layer mask at absorbing light exposures. FIG. 3E shows region 350 extending through layers 310 and 330 imaged from light at 355 nm, which is a penetrating wavelength through combined layers 310 and 330. FIG. 3F shows a top view of last exposure mask for 355 nm for FIG. 3E. FIG. 3G shows a separated ring structure after development of the two layers 310 and 320. The separated ring structure may be a gear. Other materials, absorbing wavelengths of light, and other penetrating wavelengths of light may be used depending on the application.

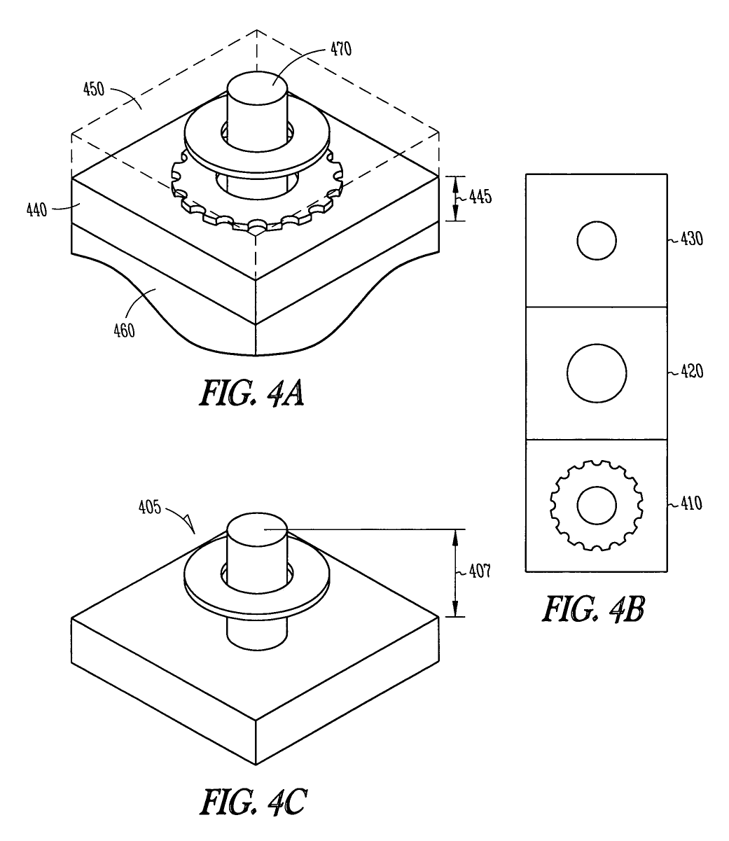

FIG. 4 depicts an embodiment of a gear on a substrate formed using multiple wavelengths. In this embodiment, mask layers 410 and 420 are used with an absorbing 244 nm wavelength of light, and mask layer 430 is used with transmitting 355 nm wavelength of light. The 244 nm masks are applied to the first two layers 440 and 450 on substrate 460. The material for the layers may be SU-8. The 355 nm mask is used to provide pinion 470 that extends above layer 450 and through layer 440 and 450 to substrate 460. Layer 440 may have a thickness 445 as small as one micron, where the entire gear 405 may have a thickness 407 of about two microns. The use of the two wavelengths allows the gear structure to be fabricated using one development processing to provide such a machine. Other embodiments are not limited to the dimensions of the embodiment discussed with respect to FIG. 4.

FIG. 5 depicts an embodiment of a stack structure 500 formed using multiple wavelengths. Stack structure 500 has multiple layers 510-1, 510-2, 510-3 . . . 510-(N-1), 510-N, where each layer is separated by distance 520. Distance 520 may be related to a given wavelength as λ/x. Each layer may be connected by pillar-like structures 540 having a distance 530 between pillar-like structures 540. In an embodiment distance 530 equals distance 520. Stack structure may be configured as an infrared stack or a matrix for other material based on properties such as material emissivity.

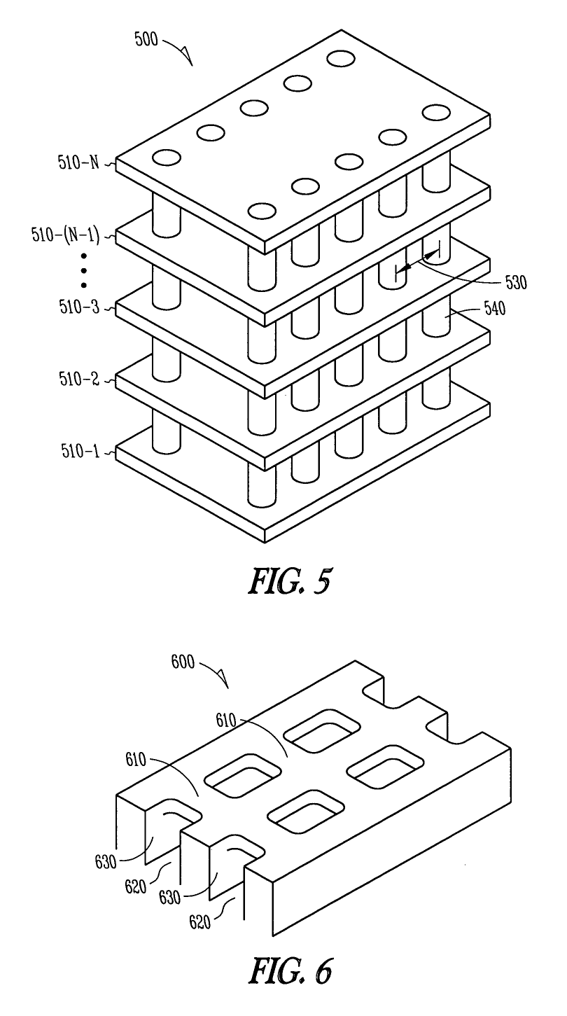

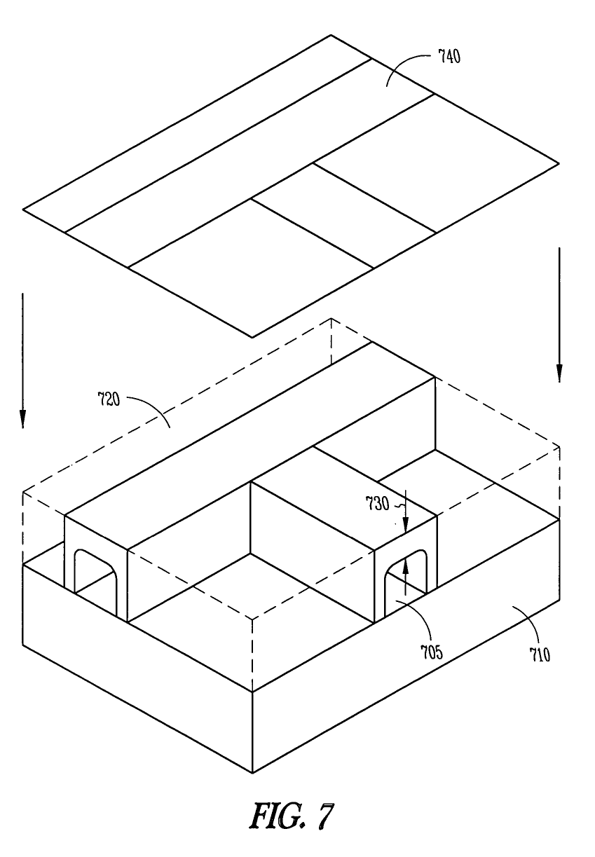

FIG. 6 depicts an embodiment of a suspended structure 600 on a substrate, where suspended structure is formed using multiple wavelengths. Suspended structure 600 includes bridges 610 over tunnels 620. The bridges may be fabricated using an absorbed wavelength and side walls of the tunnels may be fabricated using a penetrating wavelength. The bridges 610 and side walls 630 may be formed applying the wavelengths in conjunction with masks or using interferometric lithography. In an embodiment, an absorbed wavelength of 244 nm may be used. In an embodiment, a penetrating wavelength of 355 may be used. After exposure, the bridge structures over the tunnels may be realized in a single layer using one development process on the single layer.

FIG. 7 depicts an embodiment of a tunnel 705 having a T shape formed in a material 720 using multiple wavelengths. Material 720 may be SU-8 negative resist material. In an embodiment, the surface of material 720 on substrate 710 is uniformly flooded with light of an absorbing wavelength. The absorbing wavelength exposes material 720 to a depth 730 less than the thickness of material 720. The absorbing wavelength may be 244 nm. A mask 740 may be placed over the surface of material 720 and light having a penetrating wavelength may be exposed to the volume of material 720 except the volume of material 720 under mask 740. The penetrating wavelength may be 355 nm. After the two exposures, a T tunnel may be formed by developing doubly exposed material 720.

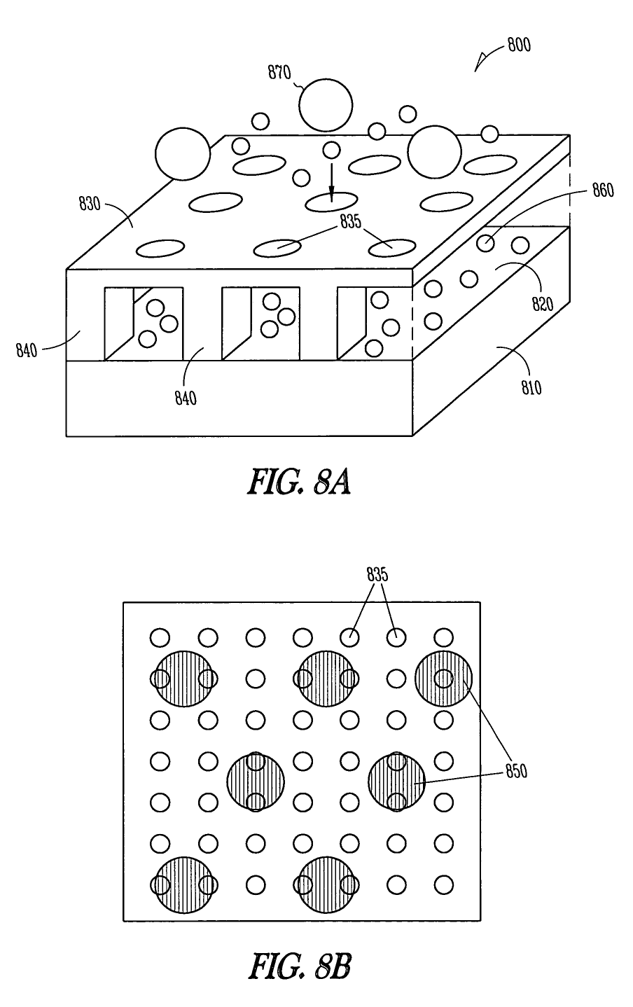

FIG. 8A depicts an embodiment of a single stage filter 800 using multiple wavelengths. Single stage filter 800 includes a substrate 810, a galley 820, and a filter surface layer 830. Galley 820 is a region between substrate 810 and filter surface layer 830 for collecting particles. Substrate 810 is connected to filter surface layer 830 by support pillars 840. Substrate 810 may be a glass substrate or other material selected for a particular filter application. Filter surface layer 830 has thickness generated by exposure to light at wavelength that is highly absorbed by a material that is placed on substrate 810 to form the filter structure. The absorbing wavelength light may be used to form filter holes 835 in filter surface layer 830 using masks or interferometric lithography. A wavelength of 244 nm in may be used to expose small holes in filter surface layer 830. Support pillars 840 may be fabricated using light at a penetrating wavelength. The penetrating wavelength light may be used with masks to fabricate support pillars 840. A wavelength of 355 nm may be used to fabricate support pillars 840. Using small holes in filter surface layer 830, only small particles 860 may enter galley 820. The small particles entering galley 820 may be optically interrogated. Large surface particles 870 not being able to pass through holes 835 of filter surface layer 830 may be cleaned off filter surface layer 820. FIG. 8B shows holes of filter surface layer 830 indicating projections 850 of support pillars 840.

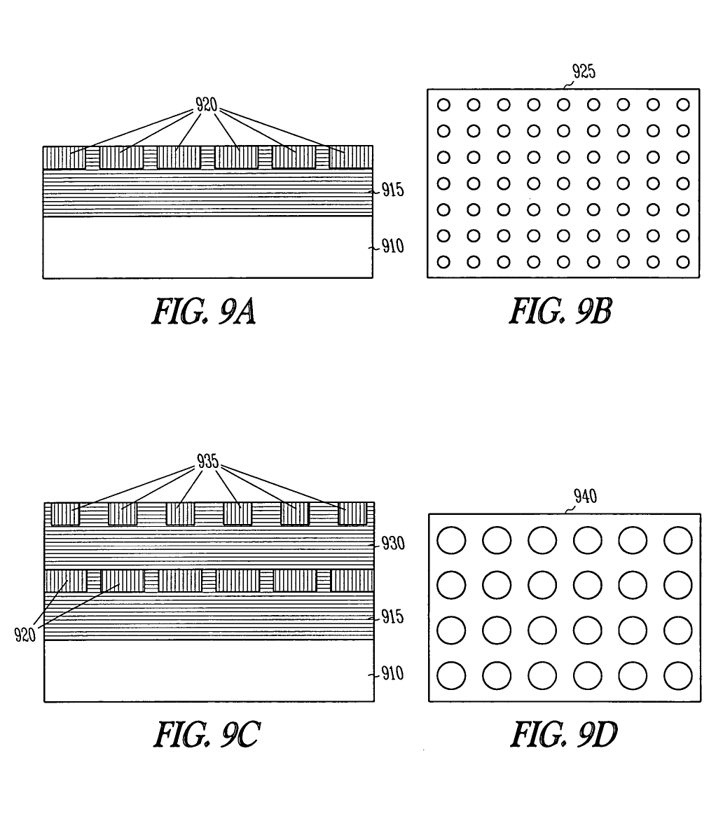

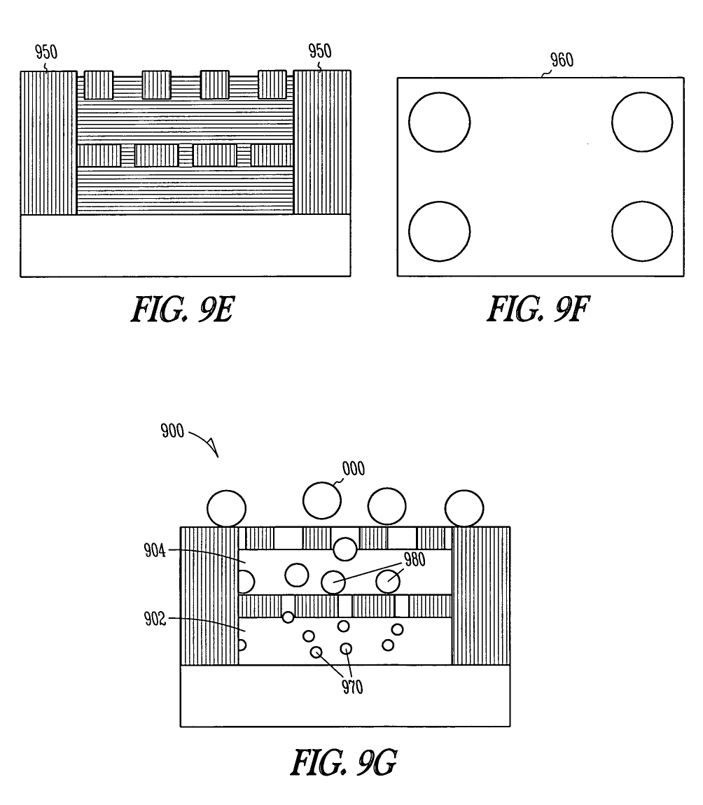

FIGS. 9A-9G depict an embodiment in which a two-stage filter may be formed using multiple wavelengths. FIG. 9A shows a layer 915 on a substrate 910 having surface regions 920 exposed to an absorbing wavelength. The absorbing wavelength may be 244 nm. The material of layer may be SU-8. FIG. 9B shows a first layer mask 925 to form exposed regions 920. FIG. 9C shows a layer 930 on layer 915, where layer 930 has surface regions 935 exposed to an absorbing wavelength. In an embodiment, surface regions 935 are larger than surface regions 920. The absorbing wavelength may be 244 nm. The material of layer 930 may be SU-8. FIG. 9D shows a second layer mask 940 to form exposed regions 935. FIG. 9E shows layer 915 and 930 exposed to light of a penetrating wavelength to provide support structures 950. FIG. 9F shows a layer mask 960 to form support structures 950 using the penetrating wavelength. The penetrating wavelength may be 355 nm. FIG. 9G shows a two stage filter 900, after developing the exposed layers 915 and 930. Small particles 970 are allowed to pass into the first stage 902 and medium particles 980 are allowed to pass into the second stage 904. Large particles 990 are prevented from entering two-stage filter 900.

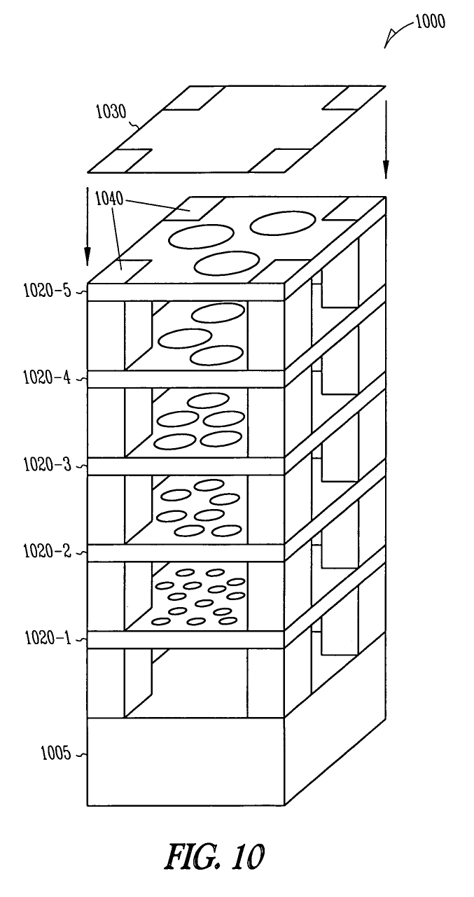

FIG. 10 depicts an embodiment of a filter stack 1000 formed using multiple wavelengths. Filter stack 1000 includes five layers 1010-1 . . . 1010-5 having surfaces with holes in which the hole sizes differ among the layers. In an embodiment, layer 1010-1 formed as the first layer on a substrate 1005 has the smallest hole size, with the layer farthest from substrate 1005 having the largest holes. In forming filter stack 1000, each layer 1010-1 . . . 1010-5 has a surface region 1020-1 . . . 1020-5, respectively, exposed to light at a wavelength that is absorbed to define surface regions 1020-1 . . . 1020-5. Surface regions 1020-1 . . . 1020-5 may be exposed to provide a short wavelength region. A 244 nm wavelength light may be use as the absorbing short wavelength. Five different masks may be used to form holes in the surface regions 1020-1 . . . 1020-5 such that regions unexposed to the short wavelength light will become holes. Further, regions in layers 1010-1 . . . 1010-5 below surface region 1020-1 . . . 1020-5, respectively, may be opened by developing these layers after all exposures are completed. A mask 1030 may be used with a long wavelength light to generate supports 1040. Light at 355 nm may be used as a long wavelength light to penetrate layers 1010-1 . . . 1010-5. Filter stack 1000 may be configured as a particle sieve. Embodiments are not limited to a five layer structure, but may use any number of layers depending on the application.

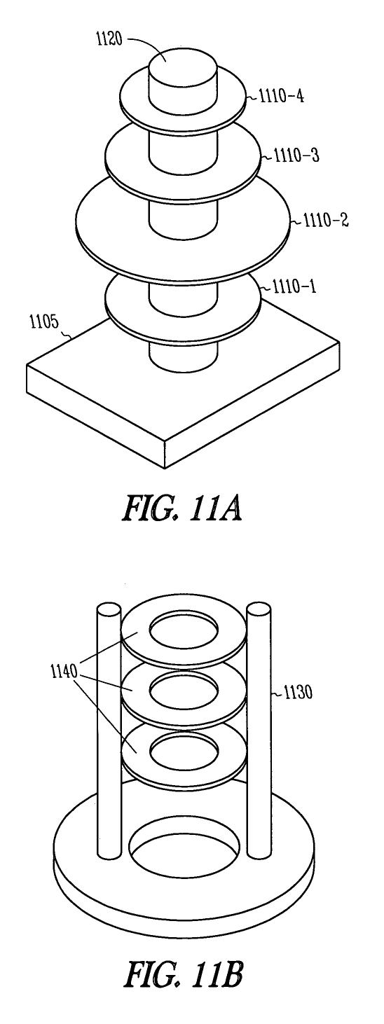

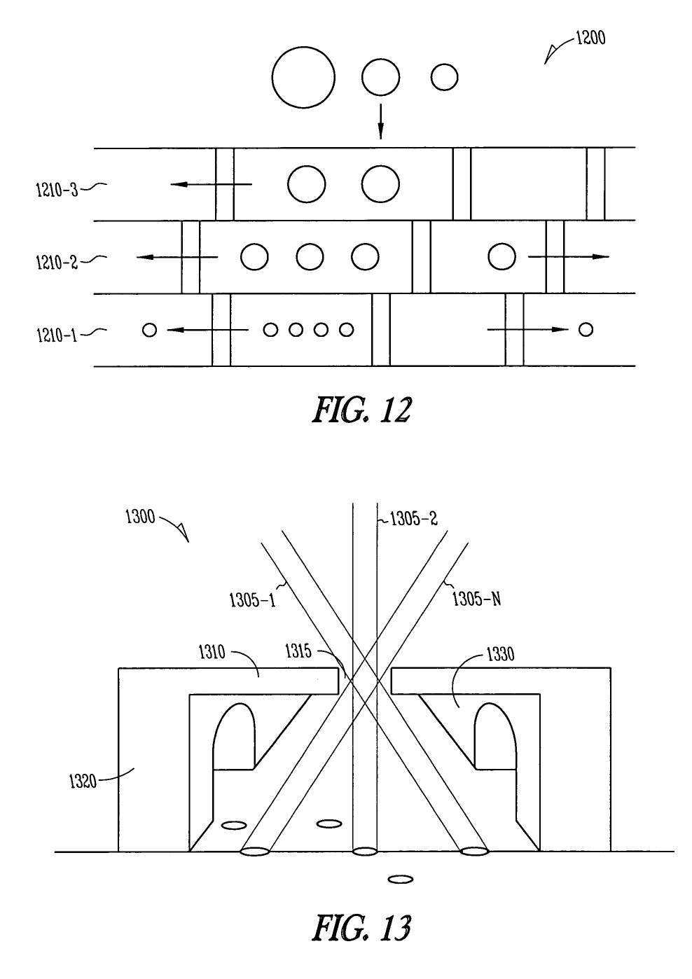

FIG. 11 A depicts an embodiment of disc stacks 1100 on a substrate 1105 formed using multiple wavelengths. Disc stacks 1100 include discs 1110-1 . . . 1110-4 aligned around a center shaft 1120. Discs 1110-1 . . . 1110-4 may be separated from each other by about one micron. Other separation distances may be used depending on the application. Discs 1110-1 . . . 1110-4 may be formed using light at an absorbing wavelength and various sized masks associated respectively with the size of each disc 1110-1 . . . 1110-4. Embodiments are not limited to a four disc structure, but may use any number of discs depending on the application. Center shaft 1120 may be formed using light at a transmitting wavelength and an appropriate size mask.

FIG. 11B shows another embodiment in which legs 1130 support discs 1140. Two legs, three legs, or four legs may be used. The number of legs used is not limited to a particular number, but is dependent on the application employing the disc with multiple legs structure. Such multiple layer structures formed in various embodiments similar to FIGS. 11A and/or 11B may be processed in one development procedure. Disc stacks may be used for ring structures, optical cavities, optical cavity arrays, suspended resonators, metal rings, and phase array antennas.

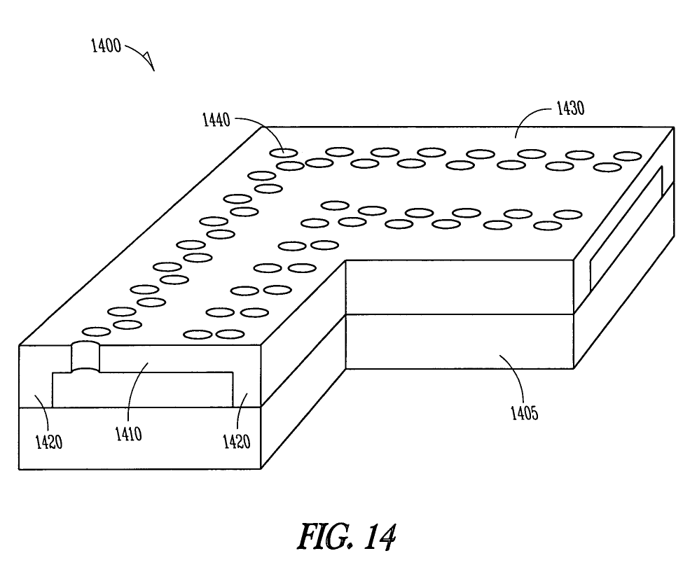

FIG. 12 depicts an embodiment of a molecular sieve 1200 formed using multiple wavelengths. Particles of various sizes may be collected in levels 1210-1, 1210-2, and 1210-3 based on the size of the particles. In an embodiment, SU-8 may be used to form levels 1210-1, 1210-2, and 1210-3. In an embodiment, the hydrophobic nature of SU-8 material allows gas to pass through levels of molecular sieve 1200, while prohibiting or limiting the flow of a liquid.

FIG. 13 depicts an embodiment of a superstructure 1300 for metal evaporation using various trajectories 1305-1, 1305-2 . . . 1305-N. Superstructure 1300 includes a roof 1310 with holes 1315, support legs 1320, and a region 1330 within superstructure 1300 through which evaporated metal passes to deposit onto a surface on which superstructure 1300 is positioned. A metal pattern is formed on the surface corresponding to the various metal vapor trajectories that may pass through holes of superstructure. Evaporated metal on other trajectories will be prohibited from reaching the surface by superstructure 1300. Roof 1310 may be formed using light at absorbing wavelength along with a mask to form holes 1315. Light at 244 nm may be used as the absorbing wavelength light. Support legs 1320 may be formed using light at a transmitting wavelength. Light at 355 nm may be used as the transmitting wavelength light. After exposing the material for superstructure 1300 to multiple wavelengths of light, the material may be developed to remove material forming holes 1315 and region 1330. Superstructure 1300 is not limited to embodiments for forming metal patterns on a surface using evaporation trajectories but may be used to evaporate other elements using evaporation trajectories for deposition onto a surface.

In an embodiment for forming 3-D features using two different wavelengths of light, a coating is applied to a substrate. The coating may be a SU-8 photo epoxy. The SU-8 photo epoxy may have a thickness of about 1 μm. Light of a first wavelength may be used to project an image onto the coating. An image may be provided using a fully penetrating 355 nm wavelength. Light of a second wavelength and corresponding image may then be projected onto the same coating. An image may be provided using a shallow penetrating 244 nm wavelength. The combination of images recorded in the single coating layer may then be processed (bake, develop, rinse and dry).

In an embodiment, a result of applying the two different wavelengths may be straight tunnels open at both ends. The walls of the tunnels may be formed by the 355 nm image as it propagates completely through the photo-sensitive layer. The tunnel roof may be created when the image projected with 244 nm light is stopped in the upper surface by high absorption leaving the underlying photosensitive material unexposed. A developer removes the unexposed material revealing the 3D form of the combined images.

In an embodiment, a method includes exposing a material to electromagnetic radiation at multiple wavelengths to provide a combined image in the material, where the combined image corresponds to images due to each of the multiple wavelengths. The material may be processed to generate a three-dimensional structure defined by the combined image. Electromagnetic energy at a first wavelength may be applied such that the electromagnetic radiation at this wavelength may pass through a portion of the material to a depth, d₁. Electromagnetic energy at another wavelength may be applied such that the electromagnetic radiation at this wavelength may pass through a portion of the material to a depth, d₂, where d₂>d₁. In an embodiment, electromagnetic radiation at another wavelength may propagate completely through the material. In an embodiment, electromagnetic energy at various wavelengths may be applied such that the electromagnetic radiation at these wavelengths may be absorbed and limited to exposing portions of the material to different depths. In an embodiment, the material is processed to remove portions of the material corresponding to the combined image. In an embodiment, the material is processed to remove portions of the material in regions of the material not exposed to multiple wavelengths.

FIG. 14 depicts an embodiment of an air-bridge optical waveguide 1400 fabricated using multiple wavelengths. Air-bridge optical waveguide 1400 may include a substrate 1405 and a waveguide region 1410 suspended above substrate 1405. Waveguide section 1410 may have support walls 1420. Support walls 1420 may be formed from photosensitive material layer or layers 1430. Photosensitive material layer or layers 1430 may include photonic crystal holes 1440. Waveguide region 1410 and photonic crystal holes 1440 may be formed in various embodiments by exposing photosensitive material layer or layers 1430 to one or more wavelengths of light followed by development of photosensitive material layer or layers 1430. Support walls 1420 may be formed from exposure to another wavelength of light followed by development of photosensitive material layer or layers 1430. Development for waveguide region 1410, photonic crystal holes 1440, and support walls may be performed in one development process.

Although specific embodiments have been illustrated and described herein, it will be appreciated by those of ordinary skill in the art that any arrangement that is calculated to achieve the same purpose may be substituted for the specific embodiments shown. This application is intended to cover any adaptations or variations of embodiments of the present invention. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description. The scope of the present invention includes any other applications in which embodiment of the above structures and fabrication methods are used. The scope of the embodiments of the present invention should be determined with reference to the claims, along with the full scope of equivalents to which such claims are entitled.

1. A method comprising:
exposing a material to light at a first wavelength; and
exposing the material to light at a second wavelength such that exposure at the first and second wavelengths are used to provide a three-dimensional feature, the second wavelength being different than the first wavelength.

2. The method of claim 1, wherein exposing the material to light at a second wavelength includes exposing the material such that light at the second wavelength penetrates through the material.

3. The method of claim 1, wherein exposing the material to light at a second wavelength includes exposing the material to light at a wavelength of 355 nm.

4. The method of claim 1, wherein exposing a material to light at a first wavelength includes exposing the material such that the light at the first wavelength is absorbed near a surface of the material.

5. The method of claim 1, wherein exposing the material to light at a first wavelength includes exposing the material to light at a wavelength of 244 nm.

6. The method of claim 1, wherein exposing a material includes exposing a photo-initiated polymer to generate a three-dimensional structure in the photo-initiated polymer.

7. The method of claim 1, wherein exposing a material includes exposing a layer of SU-8.

8. The method of claim 1, wherein the method includes removing unexposed material from around and under exposed material.

9. The method of claim 8, wherein removing unexposed material from around and under exposed material includes forming tunnel structures having roofs.

10. The method of claim 1, wherein exposing the material to light at a second wavelength includes exposing the material to light at the second wavelength to provide support features connecting an upper portion of the material to a substrate.

11. The method of claim 1, wherein exposing a material to light at first and second wavelengths includes exposing the material to form a ring structure on and separated from a substrate.

12. The method of claim 1, wherein exposing a material to light at first and second wavelengths includes exposing the material to form a bridge structure on a substrate.

13. The method of claim 1, wherein the method includes applying light at first and second wavelengths to form a multiple layer stack of a three-dimensional structure.

14. The method of claim 1, wherein exposing a material to light at first and second wavelengths includes exposing the material to form a particle sieve.

15. The method of clam 1, wherein exposing a material to light at a first wavelength and exposing the material to light at a second wavelength includes:
coating a substrate with a SU-8 photo epoxy;
projecting a first image onto the coating using light at a wavelength of 244 nm, wherein penetration of the coating is limited to less than the thickness of the coating;
projecting a second image onto the coating using light at a wavelength of 355 nm, the second image and the first image to form a combined image; and
processing the combined image.

16. The method of claim 15, wherein processing the combined image includes removing unexposed material to provide three-dimensional features from the combined image.

17. An apparatus comprising:
a substrate;
a three-dimensional structure on the substrate, the three-dimension structure having features defined by light at two different wavelengths.

18. The apparatus of claim 17, wherein the three-dimensional includes a tunnel structure.

19. The apparatus of claim 17, wherein the three-dimensional includes a particle separator.

20. The apparatus of claim 17, wherein the three-dimensional includes an infrared stack.

21. A method comprising:
exposing a material to electromagnetic radiation at multiple wavelengths to provide a combined image in the material, the combined image corresponding to images due to each of the multiple wavelengths; and
processing the material to generate a three-dimensional structure defined by the combined image.

22. The method of claim 21, wherein processing the material includes removing portions of the material corresponding to the combined image.

23. The method of claim 21, wherein processing the material includes removing portions of the material in regions of the material not exposed to the multiple wavelengths.

24. The method of claim 21, wherein the method includes forming an optical waveguide suspended above a substrate.

25. The method of claim 21, wherein forming an optical waveguide suspended above a substrate includes forming an air-bridge optical waveguide.
